(19) United States
(12) Patent Application Publication
(10) Pub. No.: US 2006/0280866 A1
(43) Pub. Date: Dec. 14, 2006

(54) Method and apparatus for mesoscale deposition of biological materials and biomaterials

(75) Inventors: Gregory J. Marquez, Albuquerque, NM (US); Michael J. Renn, Hudson, WI (US)

Correspondence Address: PEACOCK MYERS, P.C., 201 THIRD STREET, N.W., SUITE 1340, ALBUQUERQUE, NM, 87102, US

(73) Assignee: Optomec Design Company, Albuquerque, NM (US)

(21) Appl. No.: 11/251,520

(22) Filed: Oct. 13, 2005

Related U.S. Application Data
(60) Provisional application No. 60/619,434, filed on Oct. 13, 2004.

(51) Int. Cl. C23C 16/00

(52) U.S. Cl. 427/248.1; 427/2.1; 239/424; 239/290

(57) ABSTRACT

Methods and apparatus for the direct deposition or patterning of biological materials and compatible biomaterials. The method is capable of depositing biological materials and biomaterials in a computer defined pattern, and uses aerodynamic focusing of an aerosol stream to deposit mesoscale patterns onto planar or non-planar targets without the use of masks or modified environments. The aerosolized compositions may be processed before deposition (pre-processing) or after deposition on the target (post-processing). Depositable materials include, not are not limited to conductive metal precursors, nanoparticle metal inks, dielectric and resistor pastes, biocompatible polymers, and a range of biomolecules including peptides, viruses, proteinaceous enzymes, extra-cellular matrix biomolecules, as well as whole bacterial, yeast, and mammalian cell suspensions. The targets may be planar or non-planar, and are optionally biocompatible. Applications include biosensor rapid prototyping and microfabrication, lab-on-chip manufacturing, biocompatible electroactive polymer development (ambient temperature bio-production of electronic circuitry), and various additive biomaterial processes for hybrid BioMEMS, Bio-Optics, and microfabrication of biomedical devices.

### CROSS-REFERENCE TO RELATED APPLICATIONS

This application claims the benefit of the filing of U.S. Provisional Patent Application Ser. No. 60/619,434, entitled “Method and Apparatus for Mesoscale Deposition of Biological Materials and Biomaterials”, filed on Oct. 13, 2004, and the specification thereof is incorporated herein by reference.

### FEDERALLY SPONSORED RESEARCH OR DEVELOPMENT

The U.S. government has a paid-up license in this invention and the right in limited circumstances to require the patent owner to license others on reasonable terms as provided for by the terms of Contract No. N00014-99-C-0243 awarded by the U.S. Department of Defense.

### BACKGROUND OF THE INVENTION

1. Field of the Invention (Technical Field)

The present invention relates generally to the field of direct deposition or patterning of biological materials and compatible biomaterials. More specifically, the invention relates to the field of maskless mesoscale deposition of functionally active biological materials and compatible biomaterials on planar and/or non-planar targets.

2. Background Art

Note that the following discussion refers to a number of publications and references. Discussion of such publications herein is given for more complete background of the scientific principles and is not to be construed as an admission that such publications are prior art for patentability determination purposes.

Various methods for precise deposition of biological materials and biomaterials exist, such as non-contact fluid dispense techniques that utilize syringe pumps, micro dispensers, or ink jet technologies; and contact methods that utilize micro stamp, pin, or capillary processes. For example, U.S. Pat. No. 6,309,891 discloses an invention for printing small volumes of liquid biochemical samples using spring loaded plungers and a wire bonding capillary in fluid contact with reservoirs containing the liquid to be deposited. U.S. Patent Application 2003/0099708 discloses an apparatus for dispensing a suspension containing solid particles of active pharmaceutical ingredients using an ink jet-based dispensing process. U.S. Patent Application 2003/0184611 discloses a printing device that includes an elongated holder with printing pins that use capillary channels to deposit liquid samples.

While commonly used methods of depositing biological materials and biomaterials have many advantages, many aspects of the various techniques may be improved upon. For example, most printing methods that use ink jet technology have a minimum spot size of around 50 microns, and are typically prone to excessive startup time and clogging. Contact printing methods are largely limited to deposition onto planar targets.

### SUMMARY OF THE INVENTION

The present invention is a method for depositing a material, the method comprising the steps of aerosolizing a material comprising a first biological material or biomaterial, forming an aerosol stream using a carrier gas, surrounding the aerosol stream with a sheath gas to form an annular flow, subsequently passing the annular flow through no more than one orifice; and depositing the material on a target to form a deposit comprising a feature size of less than one millimeter. The method preferably further comprises the step of processing the material, and the processing step may occur before or after the depositing step. The processing step optionally comprises maintaining the deposit at a temperature sufficiently low to extend bioactivity of the material; modifying a temperature of the deposit and modifying the material or reacting the deposited material with a second material; or changing the humidity of the carrier gas or the sheath gas.

The method preferably further comprises the step of suspending the material in a buffered aqueous solution or cell suspension. A characteristic of the material selected from the group consisting of biofunctionality, structural integrity, and bioactive capability is preferably substantially preserved. The method optionally further comprises the step of modifying the hydrophobicity of the material, preferably to improve the adhesion of the material on the target. The target optionally comprises a characteristic selected from the group consisting of non-planar, biocompatible, biological, surface-modified, and polymer. The feature size is preferably between approximately 5 microns and approximately 200 microns. The method is preferably performed in ambient conditions. The deposit preferably comprises one or more bioactive sites.

The method preferably further comprises the step of reducing a flow rate of the carrier gas while retaining substantially all of the material. The method optionally comprises the step of mixing the material with a second biomaterial or biological material before the depositing step. The relative concentrations of the first biomaterial or biological material and the second biomaterial or biological material are optionally varied, preferably by varying a carrier gas rate. The depositing step optionally comprises aligning the deposit with an existing structure on the target. The method is preferably useful for one or more applications selected from the group consisting of rapid biosensor prototyping, biosensor microfabrication, surface functionalization, microarray or lab-on-a-chip patterning, biomedical device coating, tissue engineering, and biological marking.

A primary object of the present invention is to provide for an aerosol-based direct-write printing method for maskless deposition of biological materials and compatible biomaterials onto various targets.

Another object of the present invention is to provide either or both of in-flight pre-processing or post-processing treatment of the deposit to achieve the desired physical or biochemical properties of stock material prior to deposition, resulting in processed materials having preserved biofunctionality post-deposition.

Further objects of the present invention is to use aerodynamic focusing to deposit material onto various targets, and to deposit structures with dimensions well below 50 microns on planar and non-planar surfaces.

An advantage of the present invention that a wide variety of biological materials and biomaterials can be dispensed, including, but not limited to a range from high to low pH, solutions, suspensions, and living cells.

Another advantage of the present invention is that the method is not sensitive to specifics of the fluid, such as a wide viscosity range, wide range of solvents, and wide range of additives.

Yet another advantage of the present invention is that it is capable of several hours of unassisted operation.

A further advantage of the present invention is the ability to deposit on ultra thin films.

Other advantages of the present invention include the ability to deposit conformal, precise (less than 50 micron spots and sub picoliter quantities), non-contact, no-waste, and/or 3-D materials, including graded and multiple materials.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating a preferred embodiment of the invention and are not to be construed as limiting the invention. In the drawings:

FIG. 1 is a schematic of the M³D® apparatus, using pneumatic atomization;

FIG. 2 is a micrograph of deposited Protein C antibody suspension;

FIG. 3a is a micrograph of a microarray of red fluorescent protein (RFP) deposition on Thermanox substrate viewed in visible and UV light transmission and shown to have different emission intensities at two micro molar concentrations;

FIG. 3b is a micrograph of a 2500 spot microarray pattern of cDNA on amine-binding slides, showing 50 mm OD spots with a 150 mm pitch at 25×;

FIG. 4 is a schematic of an apparatus for gradient material fabrication;

FIG. 5 is a micrograph of a linear array of Extravidin protein on Thermanox target;

FIG. 6 is a micrograph of an array of 50-micron spots of Extravidin protein on Thermanox target; and

FIG. 7 is a photograph of a cell suspension deposited onto growth media.

### DESCRIPTION OF THE PREFERRED EMBODIMENTS (BEST MODES FOR CARRYING OUT THE INVENTION)

### Introduction

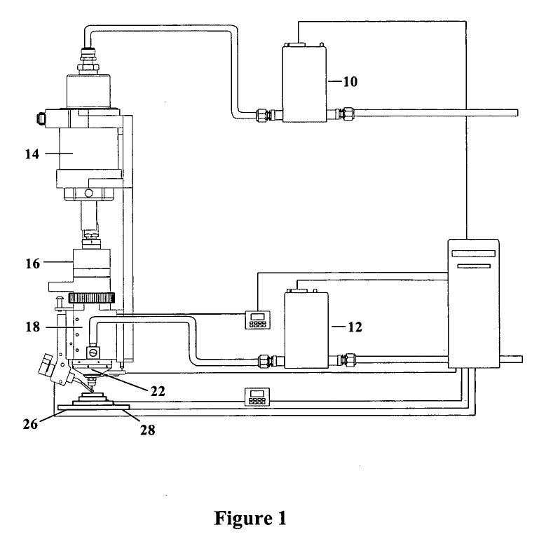

The M³D® process of the present invention is an additive direct printing technology that may be used to print biological and biocompatible structures on a variety of targets. The method is also capable of depositing multiple formulations onto the same target layer. The method is capable of depositing biological materials and biomaterials in a computer defined pattern, and preferably uses aerodynamic focusing of an aerosol stream to deposit mesoscale patterns onto a planar or non-planar target without the use of masks or modified environments. In many cases, the deposition step is followed by a processing step, in which the deposited sample is modified to the final desired state. The M³D® method is capable of blending different formulations, e.g., two equal value or one low-value and one high-value composition, in-transit, in a method in which multiple atomizers are used to aerosolize the two compositions. FIG. 1, described below, shows a preferred M³D® apparatus configured for pneumatic atomization. Such apparatus is more fully described in commonly-owned U.S. patent application Ser. No. 10/346,935, entitled “Apparatuses and Method for Maskless Mesoscale Material Deposition”, filed on Jan. 7, 2003, and the specification and claims thereof are incorporated herein by reference.

Multiple formulations are preferably deposited through a single deposition head, and blending may occur during aerosol transport or when the aerosol droplets combine on the target. Alternatively, mixing of two different materials might occur when coalesced droplets form larger droplets during aerosol transport and are deposited for selective binding of one or both materials. In this manner, the mixing occurs in parallel with atomization. The mixing could alternatively occur with serial atomization and multi-layering.

As used throughout the specification and claims, “biological material” means an autogenous or xenogenously derived material of biological origin, or material prepared from living organisms or products of living organisms. As used throughout the specification and claims, “biomaterial” is defined as a nonviable and pharmacologically inert material used to replace part of a living system or to function in intimate contact with living tissue. Biomaterials are typically used in medical devices and are preferably biocompatible; that is, intended to compatibly interact with biological systems. Biomaterials can be synthetic or natural in origin. Targets, onto which biological materials or biomaterials can be deposited, include but are not limited to electronic materials, low temperature plastics, conductive metal and polymer materials. Biological materials and biomaterials can also be deposited onto biological material targets such as cell cultures (in vitro) and tissue (in situ) and biocompatible material targets such as tissue matrices, culture ware polymers, plastics, ceramics, and metal implant devices.

The present invention is directed toward generation and additive delivery of aerosols containing functionally active biological materials and/or biomaterials. Table 1 includes examples of such biological materials. Biological materials include biological molecules, namely molecules that have been or can be isolated in readily available quantities. Another key criteria for the present invention is that the biomolecule(s) can be stabilized in aqueous solutions and maintain functionality with or without a buffer solution, which may or may not be needed as a co-delivery agent. In addition, the biomolecules are preferably transported as a solute, or in suspension, via an aqueous aerosol generated using an aerosol-generating device.

TABLE 1
Biological Materials

Proteins:
a. Fluorescing
b. Immunoactive antibodies
c. Immuno-Globulins
d. Hormones
e. Growth factors
f. Cell Adhesion (e.g. kinases)
g. Enzymes
h. Coenzymes
i. Genetically Engineered variants
Peptide subunits
Deoxyribonucleic Acid (DNA)
Ribonucleic Acid (RNA)
Oligonucleotides
Carbohydrates
Lipids
Fatty Acids
Amino Acids
Vitamins
Co-enzymes
Mineral agents
High/Low/Neutral pH reagents
Sera
Growth promoting or Growth inhibiting factors
Cells:
a. Bacterial
b. Fungal
c. Mammalian
d. Plant
e. Animal
Antigenic viral particles and viruses

Table 2 includes examples of compatible biomaterials.

TABLE 2
Compatible Biomaterials

Biocompatible Polymers:
a. Polyimide
b. Nitrocellulose
c. Cellulose Acetate
d. Teflon
e. Hydroxy Apatite
f. Polysaccharides
Biocompatible conductors:
a. Titanium (Ti)
b. Gold (Au)
c. Silver (Ag)
d. Platinum (Pt)
Saccharide solutes
Adhesion promoters/inhibitors:
a. SDS
b. Tween 20
Bioluminescent dyes

The above materials can be suspended in buffered aqueous solutions and cell suspensions for preservation of molecular and micro-organism structural integrity. The delivery of proteinaceous materials without the denaturing of bioactive capabilities is of considerable importance. Biologically active molecules in buffered colloidal dispersions and suspensions have been pneumatically and/or ultrasonically atomized to demonstrate the use of the M³D® process for two-dimensional and three-dimensional micro-patterning of biological materials and biomaterials. Similar micro-patterning of biological materials and biomaterials can be performed to produce four-dimensional structures, consisting of three linear spatial dimensions subjected to a timed growth, reaction kinetics, or timed release mechanism.

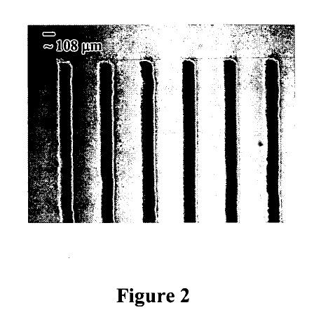

In the present invention, aerosolized droplets can contain biological molecules with diameters as small as 20 nanometers (for example, in the case of small biomolecules), and as large as tens of microns (for example, in the case of whole cells). Aerosols are preferably deposited onto various biocompatible targets. As shown in FIG. 2, Molecular Antibody to Protein C (MAb-PC), an inactivated but functional biomolecule involved in the blood-clotting cascade, may be deposited and immobilized on diagnostic device sensors. This work serves as a demonstration of the deposition of a functionally active antibody to detect the thrombolytic agent Protein C.

The M³D® process is an additive, direct-write printing technology that operates in an ambient environment and eliminates the need for lithographic or vacuum deposition techniques. Patterning is preferably accomplished by either of both of translating the deposition head under computer control while maintaining the target in a fixed position or translating the target under computer control while maintaining the deposition head in a fixed position. Once deposited, the material can be thermally processed to maintain or promote its desired state, as in the case of biomolecule deposition. Deposition of biomolecule deposits (primary layer) on polymer plastics may require incubation below room temperature to extend bioactivity until the biomolecule is reacted with a secondary layer material. Another example would be placing the immunoreactive antibody deposits (primary layer) into an incubator to promote hybridization with a secondary layer material. As in the case of whole cell deposits, the process of incubation would be employed to promote cell suspension deposits into typical sub-culture growth and confluent viability.

A medical grade, high purity carrier gas or carrier fluid, which in some cases is inert, is preferably used to deliver the aerosolized sample to the deposition module. In the case of ultrasonic atomization, the aerosol-laden carrier gas preferably enters the deposition head immediately after the aerosolization process. The carrier gas preferably comprises either or both of a compressed air or an inert gas, which may comprise a solvent vapor. A flow controller preferably monitors and controls the mass throughput of the aerosolized stream. When pneumatic atomization is employed, the aerosol stream preferably first enters a virtual impactor device that reduces the velocity and volume of gas in which the aerosol is entrained and controls the particle size of the entrained droplets or particles. In both cases, the stream is introduced into the M³D® deposition head, where an annular flow is preferably developed, consisting of an inner aerosol stream surrounded by an annular sheath gas, which is used to collimate and focus the droplet particle stream.

The aerosol stream is preferably initially collimated by passing through an orifice located on the longitudinal axis of the deposition head. The aerosol stream emerges with droplets and/or particles and is preferably contained by the sheath gas. The sheath gas preferably comprises either or both of a compressed air or an inert gas comprising a solvent vapor content. The sheath gas preferably enters the deposition head and forms an annular flow between the aerosol steam and the sheath gas stream. The sheath gas preferably forms a boundary layer that prevents particles from depositing onto the orifice wall, and focuses the aerosol stream to sizes at least as low as approximately one-twentieth the diameter of the exit orifice. The annular flow exits the deposition head preferably through a nozzle directed at the target. The annular flow focuses the aerosol stream to accomplish patterning by depositing features with dimensions typically as small as approximately 5 microns on the target, although smaller dimensions are also achievable.

The linewidths of deposited features, ranging from approximately 5-200 microns, are determined by the deposition head parameters and the corresponding flow parameters. Linewidths greater than 200 microns are achieved using a rastered deposition technique.

Furthermore, structures and devices that can be manufactured by depositing biological compositions using the maskless mesocale material deposition method include, but are not limited to existing and novel processes such as those listed in Table 3.

TABLE 3
M³D ® DWB ™ Applications

a. Functional biological molecule monolayer patterning
b. Functional biological molecule thin film patterning
c. Surface functionalization
d. Microfluidic and Biomedical Device coatings
e. Drug and Vaccine dispensing
f. Patterning Genetic and Proteomic microarrays or lab-on-chip substrates
g. Multiplexed system with multiple heads for multi-material dispensing
h. Rapid Prototyping of biosensors, and biomedical device components
i. Tissue Engineering substrate/matrix bioactive coatings
j. Engineering Tissue Constructs
k. Coating of substrates with discrete volumes/geometries
l. Printing or patterning of biological materials and compatible
biomaterials
m. Bioaerosol generation
n. Marking processes using biological materials, conjugates, or markers

### Aerosol Jet Deposition

Fabrication of biological and biocompatible structures using the M³D® process begins with the aerosolization of a solution of a liquid molecular precursor or a suspension of particles. A schematic of the apparatus, configured for pneumatic atomization, is shown in FIG. 1. The solution may alternatively be a combination of a liquid molecular precursor and particles. The invention may also be used to deposit particulate material that has been entrained in a gas stream. By way of example, and not intended as limiting, precursor solutions may be aerosolized using an ultrasonic transducer or pneumatic nebulizer 14, however Ultrasonic aerosolization is typically limited to biological solutions with viscosities of approximately 1-10 cP and typically cannot be used for any of the various whole cell suspension depositions. It can however be used for cell wall disruption and therefore cell debris aerosol generation. For solutions with viscosities of approximately 10-1000 cP, pneumatic aerosolization is used. Formulations with viscosities greater than 1000 cP require dilution with an appropriate solvent. Hybrid inorganic and biological compositions with viscosities of 100-1000 cP can be pneumatically aerosolized also. Using a suitable diluent, compositions with viscosities greater than 1000 cP may be modified to a viscosity suitable for pneumatic aerosolization. The fluid properties and the final chemical, material, and electrical properties of the deposit are dependent on the solution composition. Aerosolization of most particle suspensions is performed using pneumatics; however, ultrasonic aerosolization may be used for particle suspensions consisting of either small particles or low-density particles, with the exception of whole biological cells. In this case, the solid particles may be suspended in water, an organic solvent, inorganic solvent, and additives that maintain the suspension. These two methods allow for the generation of droplets or droplet/particles with sizes typically in the 1-5 micron size range.

The pneumatic aerosolization process typically requires a carrier gas flow rate that exceeds the maximum allowable gas flow rate through the deposition head 22. To accommodate large carrier gas flow rates, a virtual impactor 16 is preferably used in the M³D® process to reduce the flowrate of the carrier gas after aerosolization, but before injection into the deposition head. The reduction in the carrier gas flowrate is preferably accomplished without appreciable loss of particles or droplets. Virtual impaction may consist of several stages, intended to further reduce the gas flow and/or particle size distribution that flows from the previous stage. The number of stages used in virtual impactor 16 may vary, and is largely dependent on the amount of carrier gas that must be removed from the aerosol stream.

When fabricating structures of biological materials or biomaterials using the M³D® process, the aerosol stream enters through ports mounted on deposition head 22, and is directed towards an orifice, preferably millimeter-sized, preferably located on the deposition head axis. The mass throughput is preferably controlled by aerosol carrier gas flow controller 10. Inside the deposition head, the aerosol stream is preferably initially collimated by passing through the orifice. The emergent particle stream is preferably then combined with an annular sheath gas or fluid. The sheath gas most commonly comprises compressed air or an inert gas that may contain a modified solvent vapor content. The sheath gas enters preferably through the sheath air inlet, located below the aerosol inlet, and forms an annular flow with the aerosol stream. The sheath gas is preferably controlled by gas flow controller 12. The combined streams exit the chamber through a second orifice located on the axis of the deposition head and directed at target 28. This annular flow preferably focuses the aerosol stream onto the target 28 and allows for deposition of features with linewidths as small as 5 microns. The sheath gas preferably forms a boundary layer that both focuses the aerosol stream and prevents particles from depositing onto the orifice wall. This shielding effect minimizes clogging of the orifice. The diameter of the emerging stream (and therefore the linewidth of the deposit) is controlled by the orifice size, the ratio of sheath gas flow rate to carrier gas flow rate, the target speed, and the spacing between the orifice and target 28. In a typical configuration, target 28 is attached to a platen that is translated in two orthogonal directions using computer-controlled linear stages 26, so that intricate geometries may be deposited. Another configuration allows for deposition head 22 to move in two orthogonal directions while maintaining target 28 in a fixed position. The process also allows for the deposition of three-dimensional structures.

### Processing

The aerosolized biological or biocompatible compositions may be processed in-flight, during transport to the deposition head 22 (pre-processing), or once deposited on the target 28 (post-processing). Pre-processing may include, but is not limited to, humidifying or drying the aerosol carrier gas or humidifying or drying the sheath gas. Humidification or drying of the carrier or sheath gas is typically performed to change the amount of solvent or additive contained in the aerosol. The humidification process is preferably accomplished by introducing aerosolized droplets and/or vapor into the carrier gas flow. The evaporation process is preferably accomplished using an optional heating assembly to evaporate one or more of the solvent and additives, providing in-situ droplet viscosity modification.

Post-processing may include, but is not limited to, using one or a combination of the following processes: controlling the temperature of the deposited feature, subjecting the deposited feature to a reduced pressure atmosphere, heating the deposited feature thermally, or irradiating the feature with electromagnetic radiation, for example a laser. Cooling promotes short or long-term storage by inhibiting secondary biochemical reaction kinetics, hybridization, and molecular denaturing. Similarly, heating to optimized temperatures and employing other suitable environmental conditions is used to promote secondary biochemical reaction kinetics such as enzymatic catalysis, hybridization, and initiation of cellular adhesion and growth, by incubation at thermal levels equal to or greater than the physiological temperature. Post-processing of deposits generally requires temperatures ranging from approximately 4° C. to 95° C. for biological materials and 25° C. to 1000° C. for biomaterials. Deposits requiring solvent evaporation require temperatures of approximately 25° C. to 150° C. Deposits requiring cross-linking require temperatures of approximately 25° C. to 250° C. Precursor or nanoparticle-based deposits require temperatures of approximately 125° C. to 600° C., while commercial pastes typically require more conventional firing temperatures of approximately 600° C. to 1000° C.

Processing of biological material and biomaterial deposits on low-temperature targets may be facilitated by subjecting the deposit to a reduced pressure environment before the heating step, in order to aid in the removal of solvents and other volatile additives. The reduced pressure environment may also be heated.

In some cases, electromagnetic radiation may be used to process the deposited feature. Irradiation of the deposit, for example using a laser, may be performed to induce reactions including, but not limited to, heating, evaporation, cross linking, thermal decomposition, photochemical decomposition, sintering, and melting.

Deposited structures have linewidths that are determined by the deposition head, the fluid properties of the samples, and the deposition parameters, and typically have a minimum linewidth of approximately 5 microns. The maximum linewidth is approximately 200 microns. Linewidths greater than 200 microns may be obtained using a rastered deposition technique.

### Types of Structures: Biological Materials

DWB™ (Direct Write Biologics) is an extension of M³D® technology applied to the deposition of biological materials or biomaterials. DWB™ has been used to guide and deposit 0.02 μm to 30 μm diameter particles onto target surfaces. Nearly any particulate material, including biological and electronic materials, can be manipulated and deposited onto planar or conformal surfaces with mesoscale accuracy, using a maskless process. In addition, the range of materials that can be deposited is extremely broad, and includes conductive metal precursors, nanoparticle metal inks, dielectric and resistor paste materials, biocompatible polymers, and a range of biomolecules including peptides, viruses, proteinaceous enzymes, extra-cellular matrix biomolecules, as well as whole bacterial, yeast, and mammalian cell suspensions. Similarly, the choice of target varies based on the physical and chemical properties of the deposit, deposit/target compatibility, and biomolecular functional group interactions of the deposit with surface modified targets. Deposition of various biological materials (for example, those listed in Table 1) in mesoscale patterns has been demonstrated on a variety of biocompatible culturing targets.

The present invention may be applied to material deposition applications including but not limited to biosensor rapid prototyping and microfabrication, lab-on-chip manufacturing, biocompatible electroactive polymer development (ambient temperature bio-production of electronic circuitry), and various additive biomaterial processes for hybrid BioMEMS, Bio-Optics, and microfabrication of biomedical devices. Moreover, the ability to deposit biologically viable or active materials with mesoscale accuracy has potential to advance multiple bio-related applications. The process allows for fabrication of microarray chips, bio-inspired electroactive polymers, and tissue engineering applications. Table 4 lists materials that have been deposited using DWB™ according to the present invention.

TABLE 4
Materials Compatible to Deposition via Aerosol-Based Direct-Write

| Biological | |
|---|---|
| Material/Molecule | Targets |
| AFRL R5 peptide | Nitrocellulose |
| AFRL AFM2 Peptide | Aminie-Binding, Ni-binding Coated Glass |
| AFRL Anti-fd Biotin | Thermanox, Nitrocellulose, SILAS coating |
| protein | |
| AFRL Extravidin protein | Nylon, Thermanox plastic, glass |
| AFRL Red fluorescent | Nylon, Thermanox, Permanox plastics, glass |
| protein (RFP) | |
| AFRL M13 virus antigens | Nylon, Thermanox, Permanox plastics |
| Human plasma | Glass, Plastics |
| fibronectin solution | |
| 3T3 Mouse Fibroblast | Glass, Nunclon □treated plastics |
| cell/DMEM growth | |
| medium | |
| Saccharomyces cerevisiae | Agarose Growth Medium |
| yeast cell/glycerol solution | |
| Eschericia coli | Agarose Growth Medium |
| cells/glycerol solution | |
| Oligonucleotides in | Amine-Binding Coating on Glass |
| SSC buffer | |

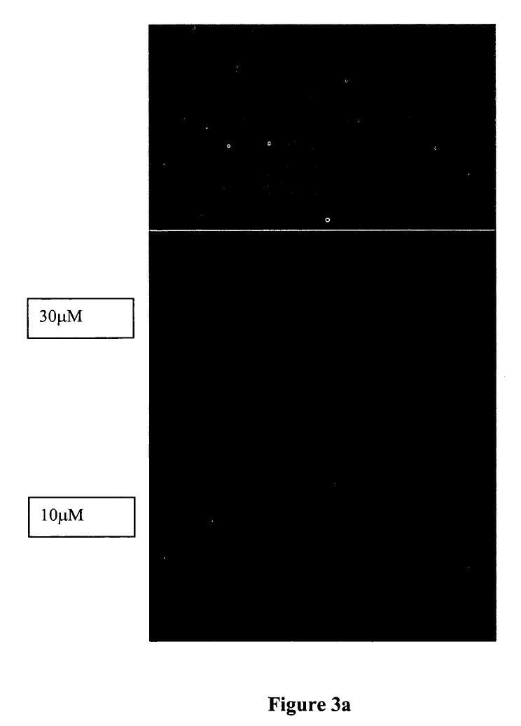

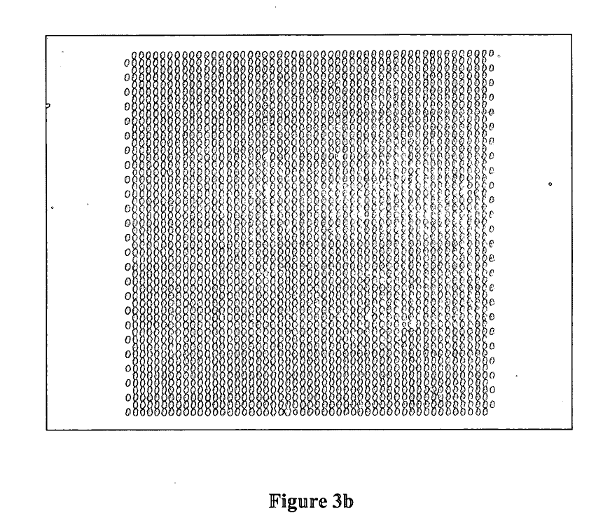

One area of DWB™ development has been the generation and additive delivery of aerosols containing functional biologically active molecules. These molecules are preferably suspended in buffered aqueous solutions for preservation of molecular structural integrity. Of primary importance is the delivery of proteinaceous materials without the denaturing of bioactive capabilities. Biologically active molecules in buffered colloidal suspensions are ultrasonically or pneumatically atomized for two-dimensional micro-patterning of biological materials. The aerosolized droplets contain the biological molecules of interest. FIG. 3a is an example of preserved bioactivity (post deposition) using red fluorescent protein (RFP) deposited at two different concentrations onto a Thermanox target. FIG. 3b is an example of a microarray pattern of cDNA on a target (2500 individual spot deposits), designed for immobilizing biomolecules by binding the biomolecules to amine functional groups.

### Types of Structures: Gradient Material Fabrication

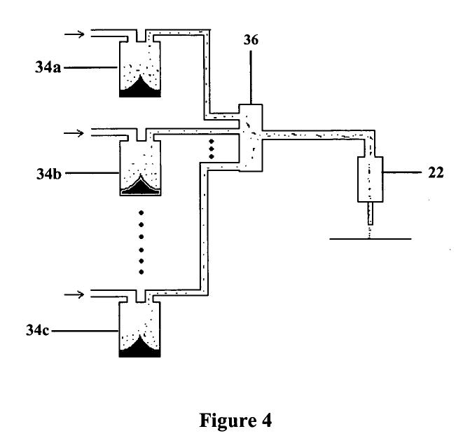

FIG. 4 depicts the M³D® process used to simultaneously deposit multiple materials through a single deposition head. Multiple atomizer units 34a-c each comprise a particular sample. The sample may be an electronic material, an adhesive, a material precursor, or a biological material or biomaterial. Each atomizer 34a-c creates droplets of the respective sample, and the droplets are preferably directed to combining chamber 36 by a carrier gas. The droplet streams merge in combining chamber 36 and are then directed to deposition head 22. The multiple types of sample droplets are then simultaneously deposited. The relative rates of deposition are controlled by the carrier gas rate entering each atomizer 34a-c. The carrier gas rates can be continuously or intermittently varied. The samples may differ in material composition, viscosity, solvent composition, suspending fluid, and many other physical, chemical, and material properties. The samples may also be miscible or non-miscible and may be reactive.

There are many advantages to gradient material fabrication. First, the method allows continuum mixing ratios to be controlled by the carrier gas flow rates. This method also allows multiple atomizers and samples to be used at the same time. Finally, mixing occurs on the target and not in the sample vial or aerosol lines. Such gradient material fabrication can deposit various types of samples, including but not limited to: UV, thermosetting, thermoplastic polymers; adhesives; solvents; etching compounds; metal inks; resistor, dielectric, and metal thick film pastes; proteins, enzymes, and other biomaterials; and oligonucleotides.

Gradient material fabrication can be practical to various applications including, but not limited to: gradient optics, such as 3D grading of a refractive index; gradient fiber optics; alloy deposition; ceramic to metal junctions; blending resistor inks on-the-fly; combinatorial drug discovery; fabrication of continuum grey scale photographs; fabrication of continuum color photographs; gradient junctions for impedance matching in RF (radio frequency) circuits; chemical reactions on a target, such as selective etching of electronic features; DNA fabrication on a chip; and extending the shelf life of adhesive materials

### Targets

Biological material and biomaterial compositions may be deposited onto any target, including but not limited to planar and non-planar biocompatible targets such as: titanium, titanium alloys, cobalt alloys, chromium alloys, gold, platinum, silver, alumina, zirconia, silicon, and hydroxy apatite; dental porcelains; nitrocellulose; polyimide, FR4, polystyrene, polycarbonate, and polyvinyl; tradename membranes and plastics such as nylon, nunclon, Permanox and Thermanox; other cell/tissue culture polymers, such as synthetic polymer scaffolds and biological structures of xenogenous and autogenous origin, glass and plastic, and biological targets; and biomedical device surfaces such as prosthetic implants made of relevant biomaterials. Additional targets include but are not limited to surface modified glass with various functional group modifiers; nitrocellulose coated glass; gold-coated polyimide; M³D®-deposited silver and platinum direct-write electrodes; and titanium structural prosthetic materials may also serve as targets.

### Applications

Applications enabled by the deposition of biological and biocompatible structures using the M³D® process include, but are not limited to, tissue engineering, drug dispensing, micro-patterning of biological arrays, and fabricating direct write biosensors. The structures may be printed on more conventional high-temperature targets such as alumina and zirconia, but may also be printed on low-temperature targets such as FR4, polyimide, and inexpensive plastics such as PET (Polyethylene terephthalate) and PEEK (Polyetherketoneketone). The M³D® process may also be used to print biological and biocompatible structures on pre-existing circuit boards, onto planar or non-planar surfaces, and into vias connecting several layers of a three-dimensional electronic circuit.

Micro-Patterned Bioactive Sites

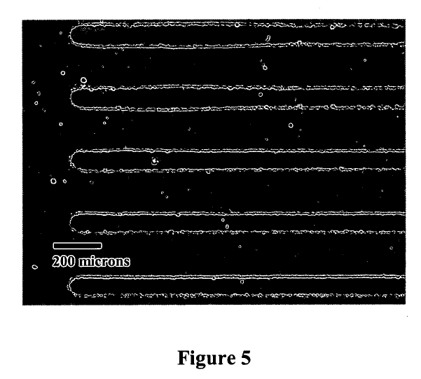

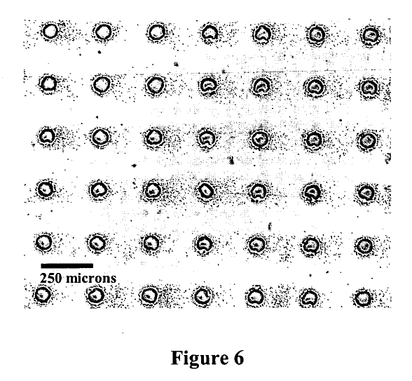

Of key importance is the ability to micro-pattern normally inactive or biologically inert materials surfaces with functionally active biological materials. In doing so, the surfaces become potentially bioactive sites. After reacting with a secondary functionally active biological material or with analyte samples, a quantifiable output signal can be detected, as in the case of depositing proteinaceous antibody patterns with localized affinity to antigenic sites of secondary antibodies, cells, and cell receptors. FIGS. 5 and 6 show various patterns of spot arrays and parallel linear rows of micro-patterned biomaterial that have been fabricated, such as deposits of biotin and extravidin bioactive sites. The two materials are proteins involved in biomolecule immobilization on various biocompatible polymer targets. Multi-layering of biotin and extravidin conjugates for cross-linking and immobilization using the M³D™ process may also be possible.

Hydrophobic/Hydrophilic Patterns

One method of micro-patterning can capitalize on the electrochemical properties of the biomolecules being deposited, the attraction or repulsion of targets, and the attraction or repulsion of target analyte biomolecules. Non-covalent interactions affect the interactions of water with other molecules, thereby affecting the structure and function of biomolecules as well as the stability of proteins and the structure of cell membranes. As such, hydrophobic side chains serve as functional groups in biomolecules, which also serve as a means of binding to or repulsing from a secondary material, or a number of materials that come into contact with the deposited bioactive material. For example, the physical constraints of Biotin biomolecules in aqueous suspensions require that the small, hydrophobic molecule be immobilized on the target. Otherwise the Biotin molecules will not adhere to the target during post processing steps. With a modified functional bioactivity, Biotin molecules covalently link to a target biomolecule extravidin/streptavidin or a larger biomolecule-conjugate, which binds to specific targets, such as gold-coated glass, more readily.

Cell Patterning

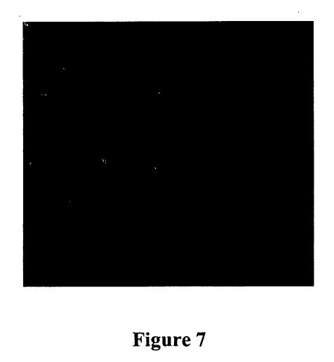

Cell patterning using the M³D™ process is possible. The process allows for selective micro-patterning of matrix materials, cells, and adhesion or signal biomolecules. Two processes that can be employed involve non-contact conformal writing of biologically active materials onto various targets. The first method involves the deposition of cell suspensions. An example is a Saccharomyces cerevisiae yeast cell suspension and growth media deposited on an agar growth media culturing target. Individual, incubated cells thrive and demonstrate viability by proliferative growth into colonies, as shown in FIG. 7. The second method involves the micro-patterning of immobilized biomolecules capable of adhering to the target and binding to cells. Observation of the tissue responses to micro-patterned biomolecules may provide insights into the temporal and spatial requirements of in-vitro engineered tissue constructs. It has been demonstrated that cellular growth and orientation will occur along the micro-patterned regions where a biologically active cell adhesion protein has been deposited. For example, fibroblast cells may adhere to target regions with pre-patterned fibronectin or laminin protein tracks.

Biosensor Fabrication

The invention can be used for the development and fabrication of biosensors for use in the detection and quantification of various biochemicals for diagnostic and various biomedical needs. In addition to biosensor work, this technology is applicable to the biomaterials R&D community, which forms an important area of biomedical engineering. Because sensor components can be fabricated with micro-size dimensions, microsensors can be fabricated, enabling a significant reduction in the size of the device, compared to conventional biosensors.

Deposition Adjacent to an Existing Biomaterial

Multiple applications exist that require deposition of an active material adjacent to a reference biomaterial. This is typical of, for example, differential measuring devices. Typically the basic steps are: i) align to a fiducial on the target, ii) deposit first material A into desired pattern, iii) switch materials, iv) realign to same fiducial or align to the previous deposit, and v) deposit second material B. Depending on details of the application, immobilization materials may be deposited to bind the biomaterial to the target. Similarly, preservative materials might also be deposited to protect biomaterial deposits. The total coating can consist of multiple layers with multiple materials in each layer. It is very important that no crossover contamination between the active materials occur.

Patterning

Patterning of a biomaterial, for example on the bottom of a culture plate, may be performed. Once such plate comprises cylindrical wells about 1 cm tall, so that the tip of the deposition head is preferably inserted into the wells. In some applications, the head may then be tilted in two angular directions to accomplish the patterning. Preferably an optical alignment system detects the position of the wells.

For these and many other applications, the alignment of deposited material to target features and to previously deposited material is often critical.

### EXAMPLE

Picoliter amounts of biomaterial were deposited onto the tips of an array of micro-needles. The micro-needles tapered from 50 microns at the base to 5 microns at the tip, and are about 200 microns tall. A video camera was used to image the entire array of micro-needles. The offset between the camera and deposition head was known, so the position information was converted to the distance to the start position (i.e. the first needle).

Although the present invention has been described in detail with reference to particular preferred and alternative embodiments, persons possessing ordinary skill in the art to which this invention pertains will appreciate that various modifications and enhancements may be made without departing from the spirit and scope of the Claims that follow, and that other embodiments can achieve the same results. The various configurations that have been disclosed above are intended to educate the reader about preferred and alternative embodiments, and are not intended to constrain the limits of the invention or the scope of the Claims. Variations and modifications of the present invention will be obvious to those skilled in the art and it is intended to cover all such modifications and equivalents. The entire disclosures of all patents and publications cited above are hereby incorporated by reference.

What is claimed is:

1. A method for depositing a material, the method comprising the steps of:
aerosolizing a material comprising a first biological material or biomaterial;
forming an aerosol stream using a carrier gas;
surrounding the aerosol stream with a sheath gas to form an annular flow;
subsequently passing the annular flow through no more than one orifice; and
depositing the material on a target to form a deposit comprising a feature size of less than one millimeter.

2. The method of claim 1 further comprising the step of processing the material.

3. The method of claim 2 wherein the processing step occurs before or after the depositing step.

4. The method of claim 2 wherein the processing step comprises maintaining the deposit at a temperature sufficiently low to extend bioactivity of the material.

5. The method of claim 2 wherein the processing step comprises modifying a temperature of the deposit and modifying the material or reacting the deposited material with a second material.

6. The method of claim 2 wherein the processing step comprises changing the humidity of the carrier gas or the sheath gas.

7. The method of claim 1 further comprising the step of suspending the material in a buffered aqueous solution or cell suspension.

8. The method of claim 1 wherein a characteristic of the material selected from the group consisting of biofunctionality, structural integrity, and bioactive capability is substantially preserved.

9. The method of claim 1 further comprising the step of modifying the hydrophobicity of the material.

10. The method of claim 9 further comprising the step of improving the adhesion of the material on the target.

11. The method of claim 1 wherein the target comprises a characteristic selected from the group consisting of non-planar, biocompatible, biological, surface-modified, and polymer.

12. The method of claim 1 wherein the feature size is between approximately 5 microns and approximately 200 microns.

13. The method of claim 1 performed in ambient conditions.

14. The method of claim 1 wherein the deposit comprises one or more bioactive sites.

15. The method of claim 1 further comprising the step of reducing a flow rate of the carrier gas while retaining substantially all of the material.

16. The method of claim 1 further comprising the step of mixing the material with a second biomaterial or biological material before the depositing step.

17. The method of claim 16 further comprising the step of varying the relative concentrations of the first biomaterial or biological material and the second biomaterial or biological material.

18. The method of claim 17 wherein the varying step comprises varying a carrier gas rate.

19. The method of claim 1 wherein the depositing step comprises aligning the deposit with an existing structure on the target.

20. The method of claim 1 useful for one or more applications selected from the group consisting of rapid biosensor prototyping, biosensor microfabrication, surface functionalization, microarray or lab-on-a-chip patterning, biomedical device coating, tissue engineering, and biological marking.
